(19) United States
(12) Patent Application Publication
(10) Pub. No.: US 2025/0362729 A1
(43) Pub. Date: Nov. 27, 2025

(54) Methods and Devices for Emulating Load Circuits having Dynamic Current Profiles

(71) Applicant: PowerLattice Technologies Inc., Camas, WA (US)

(72) Inventors: Gang Ren, Camas, WA (US); Peng Zou, Camas, WA (US); Sujith S. Dermal, Chandler, AZ (US)

(21) Appl. No.: 19/213,294

(22) Filed: May 20, 2025

Related U.S. Application Data
(60) Provisional application No. 63/650,341, filed on May 21, 2024.

(51) Int. Cl. G06F 1/324; G06F 1/3206; G06F 1/3287; H03K 5/133; H03K 5/135; H03K 7/08

(52) U.S. Cl. CPC G06F 1/324; G06F 1/3206; G06F 1/3287; H03K 5/133; H03K 5/135; H03K 7/08

(57) ABSTRACT

This application is directed to providing a configurable and scalable load that emulates a dynamic current profile of an electronic system. The load is provided by an electronic device including a control signal interface providing control data, a clock signal interface providing an operating clock signal, a load controller, and a set of load modules. The control data indicate one or more dynamic current characteristics of the load, and are applied by the load controller to generate a plurality of load control signals that are synchronized according to a temporal pattern. Each load module is controlled by a respective load control signal to generate an output signal based on the operating clock signal. The load controller controls the set of load modules to generate respective output signals according to the temporal pattern, allowing the set of load modules to operate jointly to emulate the dynamic current characteristics of the load.

### RELATED APPLICATION

This application claims priority to U.S. Provisional Patent Application No. 63/650,341, titled “Configurable and Scalable High Current Density Dynamic Load Chiplet to Emulate CPU/GPU Dynamic Current Profile,” filed May 21, 2024, which is incorporated by reference in its entirety.

### TECHNICAL FIELD

This application relates generally to electronic circuit, including, but not limited to, methods, systems, devices, and integrated circuits for providing a configurable and scalable load that emulates a dynamic current profile of an electronic device.

### BACKGROUND

A system-on-chip (SoC) consolidates multiple components of a computer, such as a processor, memory, input/output interfaces, and various peripherals, on a substrate. SoCs are widely used in modern electronics, including smartphones, tablets, and embedded systems, where space, power efficiency, and performance are critical. To manage complex power requirements of these components, a power management integrated circuit (PMIC) is employed. The PMIC is responsible for regulating, distributing, and controlling the power delivered to the SoC's various subsystems. It efficiently manages multiple voltage levels, enabling features like dynamic voltage scaling to conserve energy and ensure the SoC operates within its optimal power and thermal limits. Together, the SoC and PMIC form a system capable of handling diverse tasks with efficient power consumption, making them essential in today's compact, high-performance devices. A challenge in verifying performance of the PMIC within an SoC arises from highly variable power demands across different system configurations and use cases of the SoC.

### SUMMARY

In accordance with at least some implementations disclosed herein is the realization that the PMIC must adapt to dynamic changes in load currents and power domain activity as the SoC's functions vary with application of different processing units. This variability makes it difficult to ensure stable voltage regulation under all operating conditions. Verifying the PMIC's fast transient response to sudden current spikes, which occur when various functional blocks like central processing units (CPUs), graphics processing units (GPU), or wireless modules activate or deactivate, is particularly complex. Additionally, the involvement of firmware in controlling power management features such as DVFS (Dynamic Voltage and Frequency Scaling) introduces further complications, making it harder to isolate and test the PMIC's behavior independently. Comprehensive verification must also account for corner cases across process-voltage-temperature (PVT) variations, as well as real-world scenarios like system boot-up and sleep mode transitions, requiring extensive simulation, emulation, and hardware-in-the-loop testing.

Various embodiments of this application are directed to a configurable and scalable high current density dynamic load circuit for emulate dynamic current profiles in functional blocks (e.g., CPUs, GPUs, wireless modules) in an electronic system (e.g., an SOC). The load circuit may be applied to characterize power delivery performance of CPUs and/or GPUs of an SOC, e.g., in a lab. More specifically, the load circuit emulates dynamic current transients of the CPUs and/or GPUs of the SOC. A PMIC is tested when the CPUs and/or GPUs are replaced with the load circuit, thereby allowing the PMIC to be verified in a desirable and cost-effective way. The load circuit includes load modules and a load profile modulator. A load module includes precisely synchronized banks of active digital logics. The load profile modulator enables a selected set of load modules to operate at a configured timing and pattern. At least a number of load modules and switching characteristics (e.g., slew rate, current variation) may be adjusted to emulate a current transient profile caused by operations of the CPUs and/or GPUs. By these means, the load circuit may enable quantitative verification of power delivery performance of the SOC.

In some implementations, the load circuit includes one or more chiplets, and simulate a power density profile of the SOC. The power density profile is defined based on a plurality of profile parameters including, but not limited to, a waveform type, a ramping edge, and a current density amplitude. Further, in some implementations, a plurality of chiplets are joined together to generate a power density higher than a power threshold. In some situations, load changes among the plurality of chiplets may be synchronized within one nano-second. In some implementations, a dynamic voltage probe is applied to sense and store a voltage waveform that may be triggered by multiple sources, and the voltage waveform may be stored in the load circuit and extracted using a signal interface.

In some situations, the CPUs and/or GPUs have a current density of 5 A/mm² or higher, and a dynamic current transient (e.g., current slew rate) reaching hundreds or thousands of Amperes over a short duration of time (e.g., one nano-second or less). A conventional dynamic load devices or instruments is several orders of magnitude below the needed current density and current transient. In some implementations of this application, the high current density and sub-nano second current slew rate is realized by the load circuit that applies a load profile modulator to control operation of load modules with a configured timing and pattern.

In one aspect, an electronic device includes a control signal interface, a clock signal interface, a load controller coupled to the control signal interface, and a set of load modules coupled to the clock signal interface and the load controller. The control signal interface is configured to provide control data indicating one or more dynamic current characteristics of a load component. The clock signal interface is configured to provide an operating clock signal. The load controller is configured to generate, based on the control data, a plurality of load control signals that are synchronized according to a temporal pattern. Each load module is configured to, based on a respective load control signal, generate an output signal that switches with respect to a plurality of clock edges of the operating clock signal. The load controller is configured to control the set of load modules via the plurality of load control signals to generate respective output signals according to the temporal pattern, thereby allowing the set of load modules to operate jointly with respect to the plurality of clock edges to emulate the dynamic current characteristics of the load component.

In some implementations, the load controller further includes a load profile modulator and a set of programmable delay modules. The load profile modulator is coupled to the control signal interface, and is configured to select a subset of load modules by enabling a subset of load control signals corresponding to the subset of load modules and determine a switching time for each of the subset of load modules. The set of programmable delay modules is coupled to the load profile modulator, and is configured to generate the plurality of load control signals based on the switching time of each of the subset of load modules.

In some implementations, the electronic device includes a first chiplet and one or more second chiplets distinct from the first chiplet. The control signal interface, the clock signal interface, the load controller, and the set of load modules are integrated and formed on the first chiplet. The one or more second chiplets are configured to operate in synchronization with the first chiplet to emulate the dynamic current characteristics of the load component.

In another aspect, a method is implemented for testing an electronic system under a load condition. The method includes coupling the electronic system to an electronic device, providing control data indicating one or more dynamic current characteristics of a load component, provide an operating clock signal, generating a plurality of load control signals that are synchronized according to a temporal pattern based on the control data, and controlling a set of load modules via the plurality of load control signals to generate respective output signals according to the temporal pattern. Controlling the set of load modules further includes, for each load module, generating an output signal that switches with respect to a plurality of clock edges of the operating clock signal based on a respective load control signal. The set of load modules operate jointly with respect to the plurality of clock edges to emulate the dynamic current characteristics of the load component.

These illustrative implementations are mentioned not to limit or define the disclosure, but to provide examples to aid understanding thereof. Additional implementations are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example electronic system, in accordance with some implementations.

FIG. 2 is a perspective view of an example electronic system, in accordance with some implementations.

FIG. 3A is a block diagram of an example electronic device emulating current performance of a load component, in accordance with some implementations.

FIG. 3B is a block diagram of an example load module, in accordance with some implementations.

FIG. 4 illustrates temporal diagrams of example signals of an electronic device, in accordance with some implementations.

FIG. 5 illustrates temporal diagrams of another set of example signals of an electronic device, in accordance with some implementations.

FIG. 6A is a block diagram of an example electronic device including a voltage drop monitoring component, in accordance with some implementations.

FIG. 6B is a flow diagram of an example voltage drop compensation process implemented by an electronic device, in accordance with some implementations.

FIG. 7 is a block diagram of a load emulator system that includes a plurality of electronic devices arranged in a master-slave scheme, in accordance with some implementations.

FIG. 8 is a flow diagram of an example method for testing an electronic system (e.g., a PMIC module in FIG. 1) under an emulated load condition, in accordance with some implementations.

Like reference numerals refer to corresponding parts throughout the several views of the drawings.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

Various embodiments of this application are directed to a configurable and scalable high current density dynamic load circuit for emulate dynamic current profiles in functional blocks (e.g., CPUs, GPUs, wireless modules) in an electronic system (e.g., an SOC). The load circuit may be applied to characterize power delivery performance of CPUs and/or GPUs of a SOC, e.g., in a lab. More specifically, the load circuit emulates dynamic current transients of the CPUs and/or GPUs of the SOC. A PMIC is tested when the CPUs and/or GPUs are replaced with the load circuit, thereby allowing the PMIC to be verified in a desirable and cost-effective way. The load circuit includes load modules and a load profile modulator. A load module includes precisely synchronized banks of active digital logics. The load profile modulator selects a subset of load modules to operate according to a configured temporal pattern. At least a number of load modules and switching characteristics (e.g., slew rate, current variation) may be adjusted to emulate a current transient profile caused by operations of the CPUs and/or GPUs. By these means, the load circuit may enable quantitative verification of power delivery performance of the SOC.

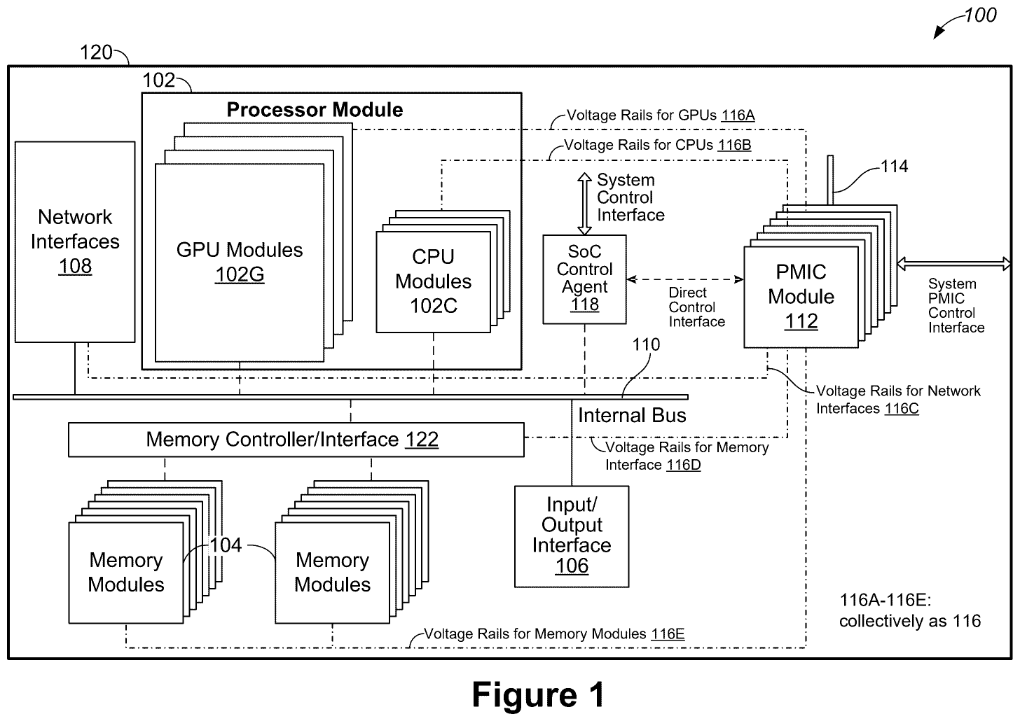

FIG. 1 is a block diagram of an example electronic system 100, in accordance with some implementations. The electronic system 100 includes at least a processor module 102, memory modules 104, an input/output (I/O) interface 106, one or more communication interfaces such as network interfaces 108, and one or more communication buses 110 for interconnecting these components. In some implementations, the I/O interface 106 allows the processor module 102 to communicate with an I/O device (e.g., a keyboard, a mouse or a trackpad). The I/O interface 106 may comply with a data communication bus standard including, but not limited to, universal serial bus (USB) and peripheral component interconnect express (PCIe). In some implementations, the communication bus(es) 110 include circuitry (sometimes called a chipset) that interconnects and controls communications among various system components included in electronic system 100. In some implementations, the electronic system 100 further includes other specialized hardware (e.g., wireless radios, graphics card, sound card, sensors).

In some implementations, the electronic system 100 further includes a PMIC module 112 configured to receive an input supply voltage 114. The PMIC module 112 is configured to modulate the received input supply voltage 114 to desired DC voltage levels, e.g., 5V, 3.3V or 1.8V, as required by various components or circuits (e.g., the processor module 102) within the electronic system 100. For example, the PMIC module 112 is configured to generate the DC voltage levels at a plurality of power rails 116 for providing power to other components (e.g., components 102-110) in the electronic system 100. Examples of the plurality of power rails 116 include, but are not limited to: one or more GPU power rails 116A, one or more CPU power rails 116B, one or more networking power rails 116C, one or more memory interface power rails 116D, and one or more memory module power rails 116E. In some implementations, the PMIC module 112 further includes a layer within a printed circuit board (PCB) or an integrated circuit (IC), and the layer is applied as an input power plane for distributing the input supply voltage 114.

In some implementations, the electronic system 100 corresponds to an SoC 120. Different components of the electronic system 100 may be formed on two or more integrated circuits distributed on two or more chips, which are further assembled on a single substrate of the SoC 120. Alternatively, in some implementations, different components of the electronic system 100 are included in an integrated circuit formed on a single substrate of the SoC 120. In an example, the SoC 120 includes one of a silicon substrate, a polymeric substrate, a glass substrate, or a printed circuit board (PCB). Examples of the polymeric substrate include, but are not limited to, polyimide (PI), polyethylene terephthalate (PET), and polydimethylsiloxane (PDMS).

In some implementations, the SoC 120 further includes an SoC control agent 118 that refers to a control mechanism or module within the SoC 120. The SoC control agent 118 is configured to manage operation of different components (e.g., components 102-110) integrated on the SoC 120. More specifically, in some implementations, the SoC control agent 118 is configured to perform one or more of: resource management, inter-component communication, power management, task scheduling, security management, thermal management. For example, the SoC control agent 118 may allocate resources like power, processing time, and memory bandwidth to different components of the SoC 120; manages communication between various components, such as coordinating data transfers between the processor module 102 and peripherals; turn off or put certain components into a low-power state when they are not in use to conserve energy; manage scheduling of different tasks or operations across processing units of the processor module 102 within the SoC 120; implements security features (e.g., using hardware security modules, encryption, and access control); or monitor temperature sensors and adjusts operation (e.g., reducing clock speeds) to prevent overheating. In an example, the SoC control agent 118 includes one or more of: a power controller, a bus controller, and a clock controller. In some implementations, the SoC control agent 118 is implemented on a firmware level, e.g., adjusting system parameters dynamically based on workloads or external conditions.

In some implementations, the processor module 102 includes a plurality of processing units. In some implementations, the processor module 102 includes two or more different types of processing units including a subset of: one or more central processing units (CPUs) 102C, one or more graphics processing units (GPU) 102G, a digital signal processor (DSP), a neural processing unit (NPU) (also called artificial intelligence (AI) accelerator), an image signal processors (ISP), a video processing unit (VPU), an audio processing unit (APU), a secure microcontroller, and a field programmable gate array (FPGA). The CPUs 102C are configured to execute instructions from software (e.g., operating systems, applications). Examples of CPU architecture include, but are not limited to, reduced instruction set computing (RISC) and complex instruction set computing (CIS). The GPUs 102G are configured to render graphics and handle tasks that require parallel processing, such as image processing, video encoding/decoding, and machine learning.

In some implementations, the network interfaces 108 is configured to enable communication between the SoC 120 and external networks, such as local area networks (LANs) or the Internet, and includes both hardware and software components that handle data transmission, reception, and protocol management. The network interfaces 108 may include one or more interfaces for Wi-Fi, Ethernet, and Bluetooth networks, each allowing the electronic system 100 to exchange data with an external source, and participate in networked applications, such as IoT (Internet of Things), mobile communications, or cloud computing.

In some implementations, the memory modules 104 include high-speed random-access memory, such as static random-access memory (SRAM), double data rate (DDR) dynamic random-access memory (DRAM), or other random-access solid state memory devices. In some implementations, the memory modules 104 include non-volatile memory, such as one or more magnetic disk storage devices, optical disk storage devices, flash memory devices, or other non-volatile solid state storage devices. In some implementations, the memory modules 104, or alternatively the non-volatile memory device(s) within the memory modules 104, include a non-transitory computer readable storage medium. In an example, a memory module 104 includes a high bandwidth memory (HBM) configured to provide a data bandwidth greater than a bandwidth threshold to support GPUs 102G. The HBM includes a plurality of memory dies that are stacked vertically on top of each other. In some implementations, the electronic system 100 further includes a memory controller 122 configured to manage memory access requests for the memory modules 104.

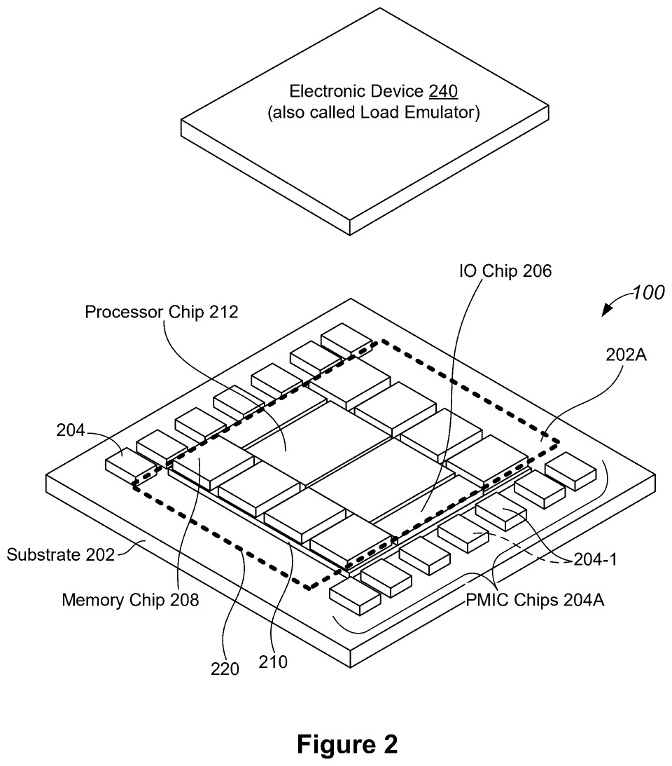

FIG. 2 is a perspective view of an example electronic system 100, in accordance with some implementations. The electronic system 100 includes an SoC 120 having a substrate 202. The substrate 202 includes a first surface 202A and a second surface (not shown) that is opposite to the first surface 202A. The substrate 202 may be one of a silicon substrate, a polymeric substrate, a glass substrate, or a PCB. Examples of the polymeric substrate include, but are not limited to, PI, PET, and PDMS. In some implementations, each electronic component of the electronic system 100 corresponds to a region of the substrate 202, and includes a portion of an integrated circuit of the SoC 120. Alternatively, in some implementations, each electronic component of the electronic system 100 includes one or more chips that are mounted onto the substrate 202, e.g., with or without an intermediate support structure 210. In an example, the substrate 202 is made of a polymeric material, and the intermediate support structure 210 is made of silicon and applied to mechanically support a plurality of components (e.g., including an IO chip 206, a memory chip 208, a processor chip 212).

In some implementations not shown, all electronic components included in the electronic system 100 are disposed on the first surface 202A of the substrate 202. Alternatively, in some implementations, a first subset of electronic components of the electronic system 100 are disposed on the first substrate 202A of the substrate 202, and a second subset of electronic components of the electronic system 100 are disposed on the second substrate of the substrate 202. In an example, one or more chips corresponding to a subset of the electronic components 102-108, 118, and 122 are disposed on the second surface. In another example, one or more chips corresponding to the PMIC module 112 are disposed on the second surface.

In some implementations, the PMIC module 112 includes a plurality of distinct PMIC chips 204, which further include a first set of PMIC chips 204A and a second set of PMIC chips 204B. The first set of PMIC chips 204A are disposed on the first surface 202A of the substrate 202, e.g., jointly with all or a subset of remainder components of the SoC 120 distinct form the PMIC module 112. The second set of PMIC chips are disposed on the second surface of the substrate 202. A rail voltage outputted by the first set of PMIC chips 204A is routed on or under the first surface 202A, e.g., by way of a configurable power plane, to access a power rail 116 of the remainder components of the SoC 120. In some implementations, a rail voltage is outputted by the second set of PMIC chips and routed vertically across the substrate 202, from the second surface to the first surface 202A, to access an associated power rail 116 located on or under the first surface 202A, e.g., by way of a configurable power plane.

In some implementations, a functional core 220 of the electronic system 100 includes an IO chip 206, a memory chip 208, a processor chip 212, and is powered by the PMIC module 112 including the plurality of PMIC chips. Alternatively, in some implementations, an electronic device 240 is coupled to the PMIC module 112 including the plurality of PMIC chips, e.g., in place of the functional core 220. The electronic device 240 includes a load emulator configured to simulate current performance (e.g., slew rates, current levels, duty cycles) of the functional core 220, thereby allowing the PMIC module 112 to be tested while the functional core 220 is not available. In an example, the functional core 220 includes a processor (e.g., CPU or GPU) configured to operate with a processor current profile. The electronic device 240 is coupled to the PMIC module 112, demanding the processor current profile from the PMIC module 112. Additionally, in some implementations, the electronic device 240 is programmable to deliver different current performance associated with different types of functional cores 220 (e.g., deliver different processor current profiles).

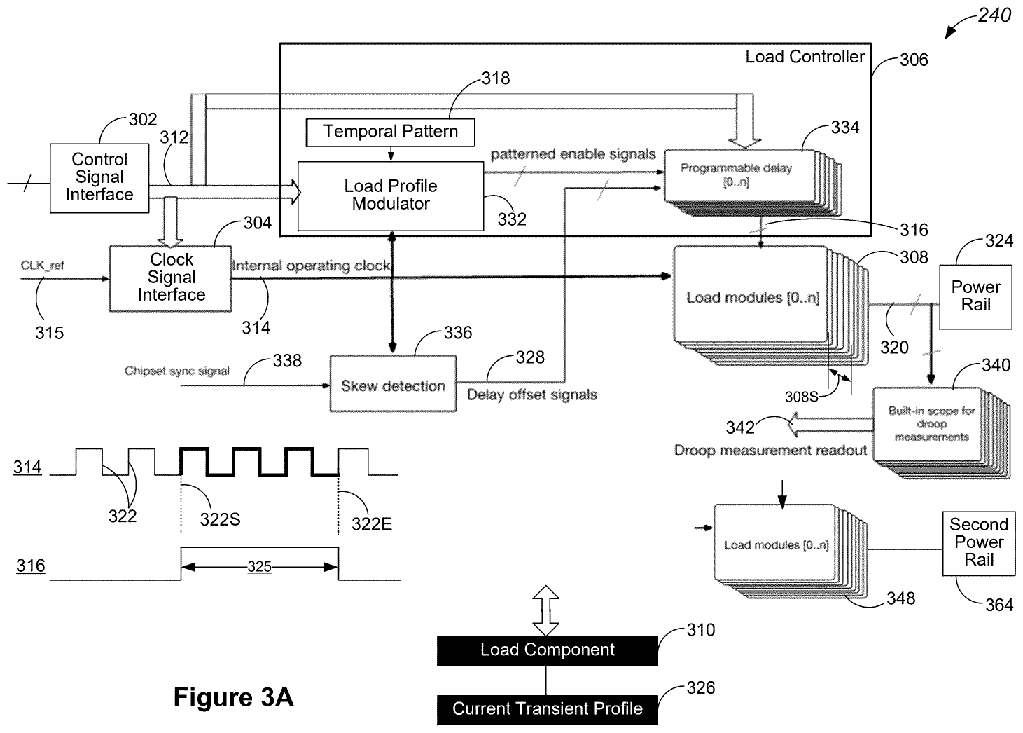

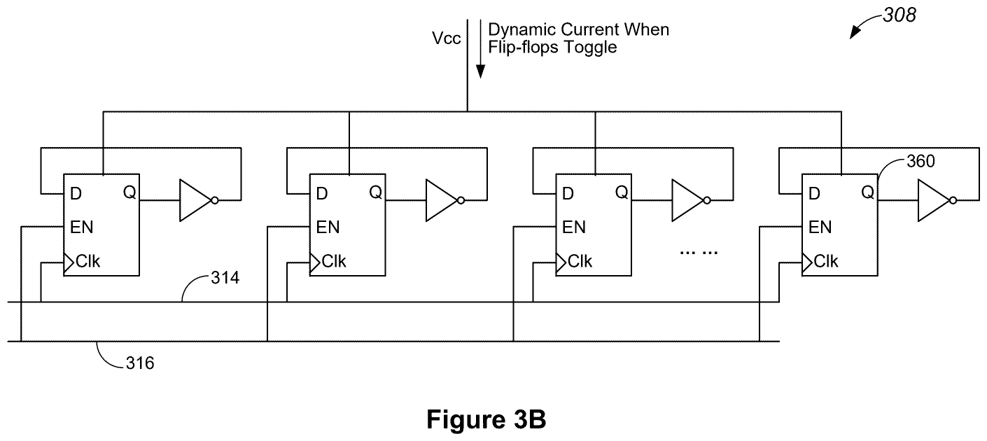

FIG. 3A is a block diagram of an example electronic device 240 emulating current performance of a load component 310, in accordance with some implementations. The electronic device 240 includes a control signal interface 302, a clock signal interface 304, a load controller 306, and a set of load modules 308. The control signal interface 302 is configured to provide control data 312 indicating one or more dynamic current characteristics of the load component 310 (e.g., functional core 220 in FIG. 2). The clock signal interface 304 is configured to provide an operating clock signal 314. The load controller 306 is coupled to the control signal interface 302, and configured to generate, based on the control data 312, a plurality of load control signals 316 that are synchronized according to a temporal pattern 318. The set of load modules 308 are coupled to the clock signal interface 304 and the load controller 306, and each load module 308 is configured to generate an output signal 320 based on a respective load control signal 316. For each load module 308, the output signal 320 switches with respect to a plurality of clock edges 322 of the operating clock signal 314. The load controller 306 is configured to control the set of load modules 308 via the plurality of load control signals 316 to generate respective output signals 320 according to the temporal pattern 318, thereby allowing the set of load modules 308 to operate jointly with respect to the plurality of clock edges 322 to emulate the dynamic current characteristics of the load component 310.

In some implementations, the load controller 306 further includes a load profile modulator 332 and a set of programmable delay modules 334. The load profile modulator 332 is coupled to the control signal interface 302, and configured to select a subset of load modules 308S by enabling a subset of load control signals corresponding to the subset of load modules and determine a switching time for each of the subset of load modules 308S. The set of programmable delay modules 334 are coupled to the load profile modulator 332, and configured to generate the plurality of load control signals 316 based on the switching time of each of the subset of load modules 308S.

In some implementations, the electronic device 240 further includes a power rail 324 to which the set of load modules 308 are coupled, and a voltage drop monitoring component 340 coupled to the power rail 324. The voltage drop monitoring component 340 is configured to generate a droop readout signal 342 indicating a voltage drop (e.g., of a voltage level of an output signal 320) at the power rail 324. Further, in some implementations, the voltage drop monitoring component 340 includes a plurality of voltage drop detectors each coupled to an output of a respective load module 308, and is configured to track the voltage drop at the power rail 324 in a distributed manner. Stated another way, each voltage drop detector may monitor a respective voltage drop of the output signal 320 of the respective load module 308, and the droop readout signal 342 is generated based on outputs of the plurality of voltage drop detectors, e.g., identifying a subset of load modules that cause the voltage drop at the power rail 324.

In some implementations, the one or more dynamic current characteristics of the load component 310 emulated by the electronic device 240 includes one or more of: an amplitude, a ramping rate, and a waveform shape of a current transient profile 326. In some implementations, the electronic device 240 is electrically coupled to a PMIC module 112 or a semiconductor package via a power rail 324. The power rail 324 is coupled to the set of load modules 308. For example, when the PMIC module 112 coupled to the electronic device 240, one or more of a voltage level and dynamic current characteristics (e.g., a current amplitude, a current ramping rate, and a current waveform shape) is monitored at the first power rail 324. The PMIC module 112 is confirmed to have a capability of driving the load component 310, when the voltage level or the dynamic current characteristics monitored at the first power rail 324 satisfy predefined criteria (e.g., match a predefined voltage or current profile of the load component 310). Conversely, the PMIC module 112 fails to show a capability of driving the load component 310, when the voltage level or the dynamic current characteristics monitored at the first power rail 324 do not satisfy the predefined criteria (e.g., does not match the predefined voltage or current profile of the load component 310).

In some implementations, the set of load modules 308 includes a number (n+1) of individual load modules 308, wherein n is a positive integer. Further, in some implementations, the load modules 308 are identical to each other, and each load module 308 is configured to generate a respective output signal 320 having a predefined voltage level Vcc and corresponding to a predefined current level if enabled. Alternatively, in some implementations, at least two of the load modules 308 are distinct from each other, and each load module 308 is configured to generate a respective output signal 320 having a predefined voltage level Vcc and corresponding to a respective current level if enabled. Currents of the at least two of the load modules 308 are distinct from each other. Additionally, in some implementations, the set of load module 308 are coupled in parallel to one another, and the output signals 320 of the set of load modules 308 are coupled to one another. The set of load modules 308 may provide the predefined voltage level Vcc via a common output signal 320. Currents of the set of load modules 308 are combined, and each load module 308 is enabled by the load control signal 316 to contribute the same predefined current level and the respective current levels to an output current of the output signal 320, e.g., during a respective duty cycle 325.

In some implementations, the respective duty cycle 325 of each load control signal 316 has a start edge and an end edge, and the start edge and/or the end edge is synchronized with a respective clock edge 322. Referring to FIG. 3A, in an example, the start edge of the load control signal 316 may overlap with a respective start clock edge 322S, and the end edge of the load control signal 316 may overlap with a respective end clock edge 322E. Each of the respective clock edges 322S and 322E may be a rising edge or a falling edge of the operating clock signal 314. In an example not shown, the start edge of the load control signal 316 may have a start delay with respect to a respective start clock edge 322S, and the end edge of the load control signal 316 may have an end delay with respect to a respective end clock edge 322E. The start delay and the end delay may be controlled by the corresponding load controls signal 316.

In some implementations the set of load modules 308 includes a plurality of load modules 308 (e.g., more than one load module), and the plurality of load modules 308 are controlled by the plurality of load controls signals 316 to switch simultaneously with respect to each of the plurality of clock edges 322. For instance, the plurality of load modules 308 are enabled simultaneously at the respective start clock edge 322S or disabled simultaneously at the respective end clock edge 322E, thereby providing a largest current ramping rate the plurality of load modules 308 may provide.

In some implementations, the clock signal interface 304 includes a clock generator (e.g., a phase lock loop (PLL) circuit), and the clock generator is coupled to the control signal interface 302, and configured to receive a reference clock signal 315 and generate the operating clock signal 314 based on the reference clock signal 315 and the control data 312. The reference clock signal 315 has a reference clock frequency that is lower than a frequency of the operating clock signal 314.

In some implementations, the electronic device 240 further includes a chiplet synchronization module 336 configured to obtain a first chiplet control signal 338 and generate a first chiplet delay offset 328 common to the respective output signals 320 of the set of load modules 308. Each respective output signal 320 generated by the corresponding load module 308 further has a respective module-level delay offset controlled by the respective load control signal 316, e.g., according to the temporal pattern 318. Stated another way, each respective output signal 320 has a respective delay with a reference time (e.g., at least shared by the set of load modules 308), and the respective delay is a sum of the first chiplet delay offset 328 and the respective module-level delay offset.

In some implementations, the set of load modules 308 include a first set of load modules 308 coupled to a first power rail 324, and the electronic device 240 further includes a second set of load modules 348 coupled to a second power rail 364. The first set of load modules 308 and the second set of load modules 348 are configured to operate concurrently to emulate the dynamic current characteristics of the first power rail 324 and the second power rail 364 of the load component 310, respectively. Further, in some implementations, the second set of load modules 348 may be controlled by the plurality of load control signals 316 and the operating clock signal 314.

FIG. 3B is a block diagram of an example load module 308, in accordance with some implementations. In some embodiments, the load module 308 further includes one or more flip-flop circuits 360 coupled to one another in parallel, and is configured to operate (e.g., toggle periodically) according to the operating clock signal 314 during a duty cycle 325 defined according to the respective module control signal 316. In some embodiments, the load module 308 delays the operating clock signal 314 based on the respective module control signal 316 and feeds a delayed clock signal to the one or more flip-flop circuits 360.

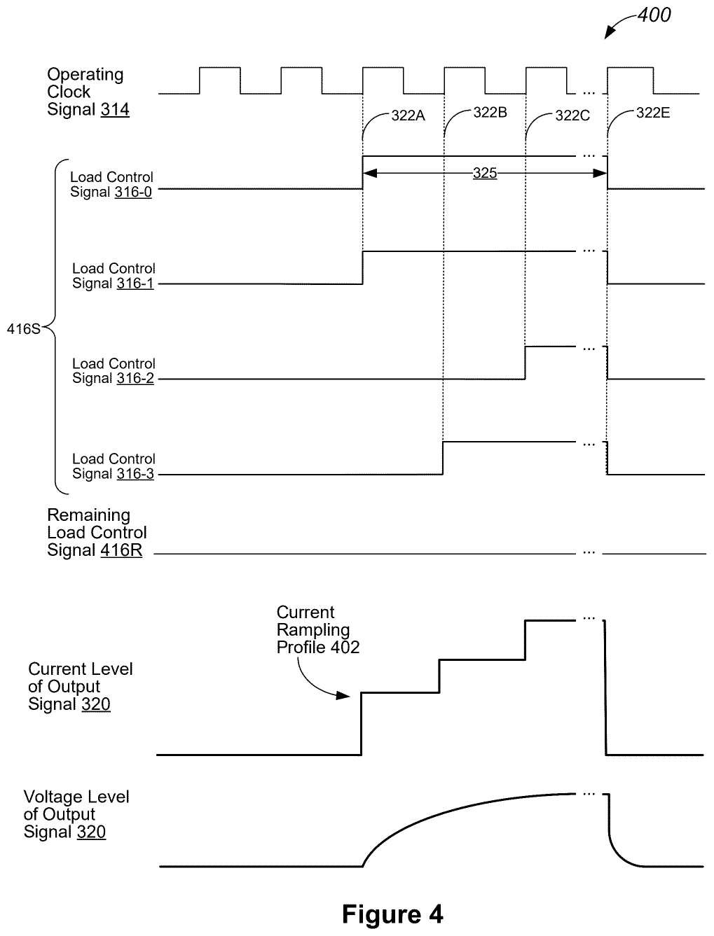

FIG. 4 illustrate temporal diagrams of example signals 400 of an electronic device 240, in accordance with some implementations. A load profile modulator 332 selects a subset of load modules 308S, and determines a switching time for each of the subset of load modules 308S. A set of programmable delay modules 334 are controlled by the load profile modulator 332 to generate a plurality of load control signals 316 based on the switching time of each of the subset of load modules 308S. The switching time of each load module 308 corresponds to a start time and/or an end time of a duty cycle 325 of a corresponding load control signal 316 generated by the respective load module 308. More specifically, in some implementations, the plurality of load control signals 316 include a first subset of load control signals 416S, and each of the first subset of load control signals 416S is configured to select a respective load module 308S to operate with a respective switching time of the respective load module 308S. Further, in some implementations, the first subset of load control signals 416S are applied to enable a subset of load modules 308S (e.g., load modules 308S) according to an ordered sequence based on their respective switching times, and currents of the subset of load modules 308S are gradually aggregated to provide a stair-like current ramping profile 402.

Referring to FIG. 4, in some implementations, the first subset of load control signals 416 include load control signals 316-0, 316-1, 316-2, and 316-3 that switch at respective rising edges of the operating clock signal 314 according to a temporal pattern 318. Each of the first subset of load control signals 416S includes load control signals 316-0, 316-1, 316-2, and 316-3 has a respective duty cycle 325. In this example, the load control signals 316-0 and 316-1 are enabled at a first clock edge 322A concurrently, and the load control signals 316-3 and 316-2 are enabled at two successive clock signal edges 322B and 322C, respectively. The subset of load modules 308S (e.g., four respective load modules controlled by the load control signals 316-0 to 316-3) are enabled at respective clock signal edges 322A to 322C to create the stair-like current ramping profile 402 and generate an output signal 320.

In some situations, the duty cycles 325 of the first subset of load control signals 416S are terminated at an end clock edge 322E. The current ramping profile 402 drops to zero, and the voltage level of the output signal 320 drops to zero at a falling rate that is greater than a rising rate corresponding to the temporal pattern 318. It is noted that, in some implementations, the duty cycles 325 of the first subset of load control signals 416S are not terminated at the same end clock edge 322E. Each of the first subset of load control signals 416S is independently set to enable a target falling rate of the output signal 320.

In some implementations, the plurality of load control signals 316 include a second subset of load control signals 416R (also called remaining load control signals 416R), and each of the second subset of load control signals 416R is configured to disable the respective load modules. Stated in another way, each remaining load control signal 416R distinct from the first subset of load control signals 416S is not enabled and has no duty cycle 325.

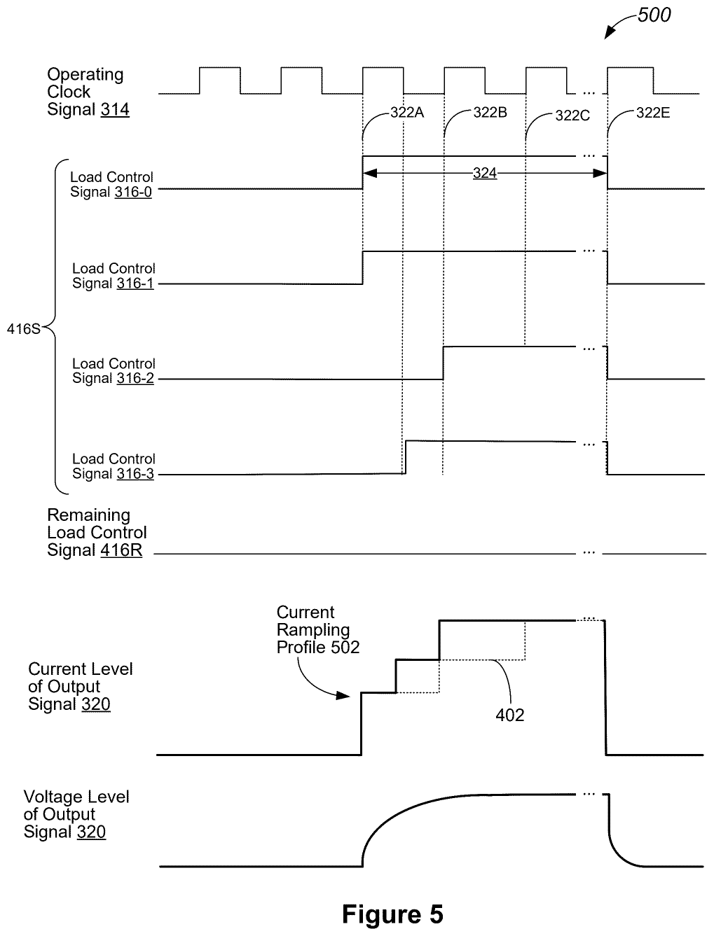

FIG. 5 illustrate temporal diagrams of another set of example signals 500 of an electronic device 240, in accordance with some implementations. A first subset of load control signals 416 include load control signals 316-0, 316-1, 316-2, and 316-3 that switch at respective rising edges of the operating clock signal 314. In this example, the load control signals 316-0 and 316-1 are enabled at a first clock edge 322A concurrently, and the load control signals 316-3 and 316-2 are enabled concurrently at a second clock edge 322B. The subset of load modules 308S (e.g., four respective load modules controlled by the load control signals 316-0 to 316-3) are enabled at respective clock signal edges 322A to 322C to create a stair-like current ramping profile 502 and generate an output signal 320. Compared with signals 400, the load control signals 316-2 and 316-3 of the signal 500 are enabled earlier, thereby causing an increase of a ramping rate of the current level of the output signal 320.

In some implementations, one or more dynamic current characteristics of a load component 310 emulated by the electronic device 240 (FIG. 3A) includes one or more of: an amplitude, a ramping rate, and a waveform shape of a current transient profile 326. The current ramping profile 502 of FIG. 5 corresponds to a first ramping rate of a first transient profile, and the current ramping profile 402 of FIG. 4 corresponds to a second ramping rate of a second transient profile. The first ramping rate of the first current transient profile is greater than the current ramping rate of the second current transient profile, and a set of first load modules 308S is enabled according to the same order and different switching times to emulate both the first current transient profile and the second current transient profile. At least one of the set of first load modules 308S has an earlier switching time for the first current transient profile than that for the second current transient profile.

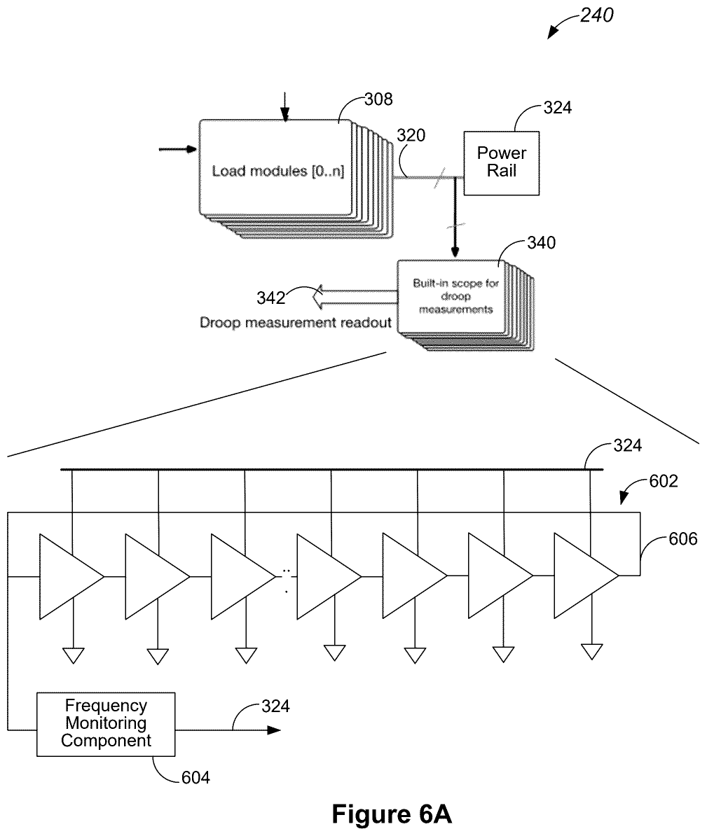

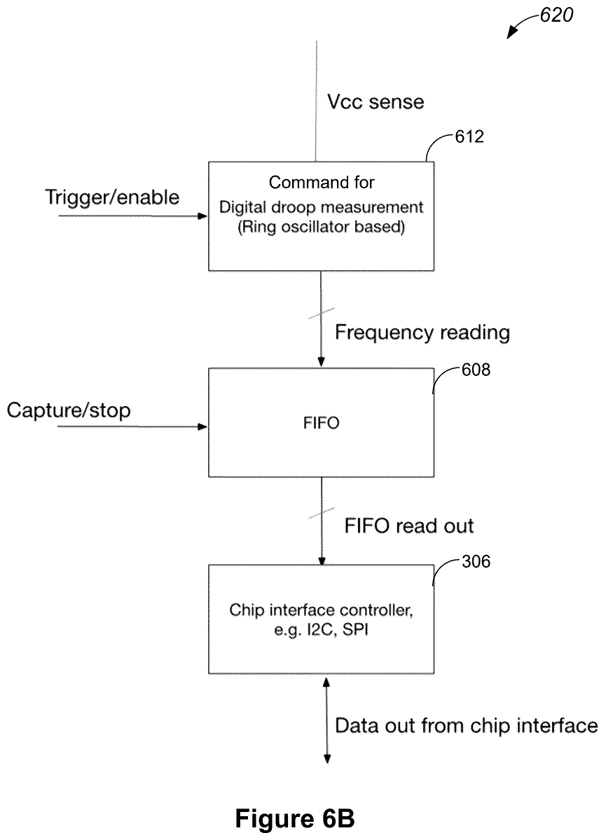

FIG. 6A is a block diagram of an example electronic device 240 including a voltage drop monitoring component 340, in accordance with some implementations, and FIG. 6B is a flow diagram of an example voltage drop compensation process 620 implemented by an electronic device 240, in accordance with some implementations. As explained above, the electronic device 240 may include a power rail 324 and a voltage drop monitoring component 340. A set of load modules 308 is coupled to the power rail 324, so is the power rail 324. The voltage drop monitoring component 340 is configured to generate a droop readout signal 342 indicating a voltage drop (e.g., of a voltage level of an output signal 320) at the power rail 324. Further, in some implementations, the electronic device 240 is electrically coupled to a PMIC module 112 via the power rail 324, and power performance of the PMIC module 112 is determined based on the droop readout signal 342.

In some implementations, the voltage drop monitoring component 340 includes a ring oscillator 602 driven by the power rail 324 and a frequency monitoring component 604, and the frequency monitoring component 604 is configured to monitor a frequency of a periodic signal 606 outputted by the ring oscillator 602 and determine the droop readout signal 342 based on the frequency of the periodic signal 606.

In some implementations, the voltage drop monitoring component 340 is configured to generate the droop readout signal 342 in response to a command 612, according to a predefined schedule, periodically, or upon detection of a signature voltage change event (e.g., at least a certain level of a voltage drop). In some implementations, a first-in-first-out (FIFO) memory 608 is configured to store the droop readout signal 342, and the droop readout signal 342 includes data samples corresponding to a signature voltage change event.

Referring to FIG. 6A, in some implementations, a command 612 is obtained for measuring a voltage drop of an output signal 320, e.g., provided to the power rail 324. A frequency generated by the ring oscillator 602 is determined at a sampling rate, and data samples of the frequency of the ring oscillator 602 may be stored in the FIFO memory 608. The data samples are fed to the load controller 306, allowing the load controller 306 to adjust a voltage level of the output signal 320. A closed loop is formed among the load controller 306, the load modules 308, and the voltage drop monitoring component 340 to compensate for a voltage drop of the output signal 320. In some implementations, the data samples are communicated to the load controller 306 via a two-wire serial communication (I2C) interface or a serial peripheral interface (SPI).

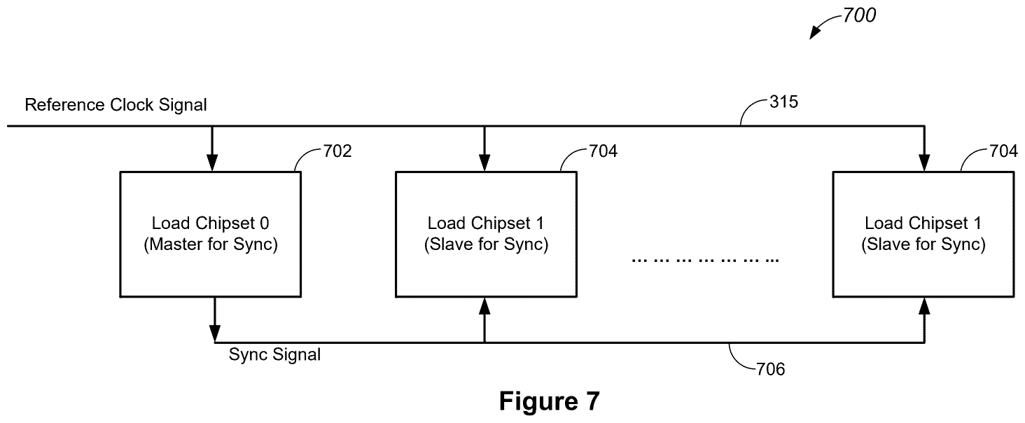

FIG. 7 is a block diagram of a load emulator system 700 that includes a plurality of electronic devices 240 arranged in a master-slave scheme, in accordance with some implementations. An electronic device 240 includes a control signal interface 302, a clock signal interface 304, a load controller 306, and a set of load modules 308. The load controller 306 is configured to control the set of load modules 308 via a plurality of load control signals 316 to generate respective output signals 320 according to a temporal pattern 318, thereby allowing the set of load modules 308 to operate jointly to emulate dynamic current characteristics of a load component 310. The load emulator system 700 includes a first chiplet 702 on which the control signal interface 302, the clock signal interface 304, the load controller 306, and the set of load modules 308 of the electronic device 240 are integrated and formed. The load emulator system 700 further includes one or more second chiplets 704 distinct from the first chiplet 702. The one or more second chiplets 704 are configured to operate in synchronization with the first chiplet 702 to emulate the dynamic current characteristics of the load component 310, e.g., by receiving the same reference clock signal 315.

In some implementations, the first chiplet 702 acts as a master chiplet configured to control synchronization among the first and second chiplets 702 and 704. Each of the second chiplets 704 is distinct from the master chiplet and acts as a salve chipelet. Each second chiplet 704 is configured to receive a respective chiplet control signal 706 from the master chiplet to control a respective chiplet delay offset on the respective remainder chip substrate. In some implementations, the first and second chiplets 702 and 704 are identical to each other. Each of the first and second chiplets 702 and 704 is configured to obtain a respective chiplet control signal to control a respective chiplet delay offset with respect to a respective remainder set of chiplets. The first chiplet 702, as a master chiplet, generates a first chiplet control signal 338 to enable a first chiplet delay offset 328, while each second chiplet 704, as a slave chiplet, receives a respective chiplet control signal 706 from the master chiplet to control a respective chiplet delay offset.

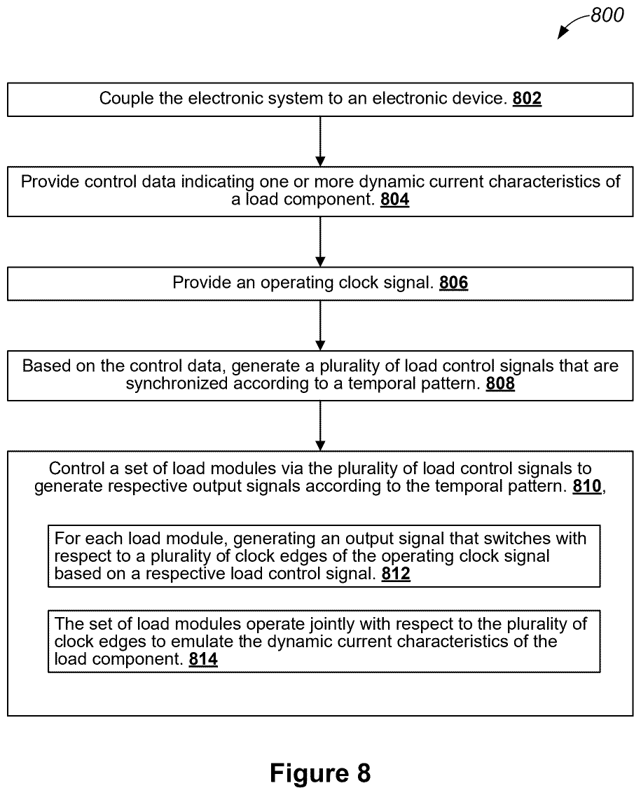

FIG. 8 is a flow diagram of an example method 800 for testing an electronic system (e.g., a PMIC module 112 in FIG. 1) under an emulated load condition, in accordance with some implementations. The electronic system is coupled (operation 802) to an electronic device 240, which is configured to emulate a load component 310 operating under the emulated load condition. Control data 312 indicates (operation 804) one or more dynamic current characteristics of the load component 310, and is provided to the electronic device 240. An operating clock signal 314 is provided (operation 806), e.g., generated by a clock signal interface 304 based on a reference clock signal 315. Based on the control data 312, the electronic device 240 (specifically, a load controller 306) generates (operation 808) a plurality of load control signals 316 that are synchronized according to a temporal pattern 318. A set of load modules 308 are controlled (operation 810) via the plurality of load control signals 316 to generate respective output signals 320 according to the temporal pattern 318. For each load module 308, an output signal 320 is generated (operation 812) to switch with respect to a plurality of clock edges 322 of the operating clock signal 314 based on a respective load control signal 316. The set of load modules 308 operate jointly (operation 814) with respect to the plurality of clock edges 322 to emulate the dynamic current characteristics of the load component 310.

In some implementations, the method 800 further includes selecting a subset of load modules 308S by enabling a subset of load control signals 316S corresponding to the subset of load modules 308S and determining a switching time for each of the subset of load modules 308S. The method 800 further includes generating the plurality of load control signals 316 based on the switching time of each of the subset of load modules 308S.

In some implementations, the plurality of load control signals 316 include a first subset of load control signals 416S (e.g., in FIGS. 4 and 5). The method 800 further includes applying each of the first subset of load control signals 416S to select a respective load module to operate with a respective switching time of the respective load module. Further, in some implementations, the method 800 includes applying the first subset of load control signals 416S to enable a subset of load modules 308S according to an ordered sequence based on their respective switching times. Currents of the subset of load modules 308S are gradually aggregated to provide a stair-like current ramping profile 402 or 502.

In some implementations, the plurality of load control signals 316 include a second subset of load control signals 416R (FIG. 4). The method 800 includes applying each of the second subset of load control signals 416R to disable the respective load module.

In some implementations, the method 800 includes receiving a reference clock signal 315 and generating the operating clock signal 314 based on the reference clock signal 315 and the control data 312.

In some implementations, each load module 308 further includes one or more flip-flop circuits 360 coupled to one another in parallel. The method 800 includes delaying the operating clock signal 314 based on the respective module control signal 316 and feeding a delayed clock signal to the one or more flip-flop circuits. Alternatively, in some embodiments, each load module 308 further includes one or more flip-flop circuits 360 coupled to one another in parallel, and is configured to operate (e.g., toggle periodically) according to the operating clock signal 314 during a duty cycle 325 defined according to the respective module control signal 316.

In some implementations, the set of load modules 308 are identical to each other. Conversely, in some implementations, at least two of the set of load modules 308 are different from each other.

In some implementations, the electronic device 240 240 includes a first chiplet 702 702 on which a control signal interface 302, a clock signal interface 304, a load controller 306, and the set of load modules 308 are integrated and formed, and one or more second chiplets 704 distinct from the first chiplet 702. The method 800 includes operating the one or more second chiplets 704 in synchronization with the first chiplet 702 to emulate the dynamic current characteristics of the load component 310. Further, in some implementations, the method 800 further includes, at each of the first and second chiplets 704, obtaining a respective chiplet control signal to control a respective chiplet delay offset with respect to a respective remainder set of chiplets.

In some implementations, the method 800 includes obtaining a first chiplet control signal 338 and generating a first chiplet delay offset 328 common to the respective output signals of the set of load modules 308. Each respective output signal 320 further has a respective module-level delay offset controlled by the respective load control signal 316.

In some implementations, the method 800 includes coupling a power rail 324 to the set of load modules and generating a droop readout signal 342 indicating a voltage drop at the power rail 324. Further, in some implementations, the method 800 includes coupling a ring oscillator 602 to the power rail 324, monitoring a frequency of a periodic signal 606 outputted by the ring oscillator 602, and determining the droop readout signal 342 based on the frequency of the periodic signal 606. In some implementations, the method 800 includes generating the droop readout signal 342 in response to a command 612, according to a predefined schedule, periodically, or upon detection of a signature voltage change event. In some implementations, the method 800 further includes storing the droop readout signal 342 in a FIFO memory 608. The droop readout signal 342 includes data samples corresponding to a signature voltage change event. In some implementations, the electronic device 240 is electrically coupled to a PMIC module 112 via the power rail 324. The method 800 includes determining power performance of the PMIC module 112 based on the droop readout signal 342.

In some implementations, the electronic device 240 is electrically coupled to a PMIC module 112 or a semiconductor package via a power rail 324 of the set of load modules 308.

In some implementations, the one or more dynamic current characteristics of the load component 310 includes one or more of: an amplitude, a ramping rate, and a waveform shape of a current transient profile 326. Further, in some implementations, a first ramping rate of a first current transient profile is greater than a current ramping rate of a second current transient profile. The method 800 includes enabling a set of first load modules according to the same order and different switching times to emulate both the first current transient profile and the second current transient profile. At least one of the set of first load modules having an earlier switching time for the first current transient profile than that for the second current transient profile.

In some implementations, the set of load modules 308 includes a plurality of load modules. The method 800 includes controlling the plurality of load modules by the plurality of load controls signals 316 to switch simultaneously with respect to each of the plurality of clock edges 322.

In some implementations, the set of load modules 308 includes a first set of load modules coupled to a first power rail 324. The electronic device 240 further includes a second set of load modules coupled to a second power rail 364. The method 800 includes operating the first set of load modules and the second set of load modules concurrently to emulate the dynamic current characteristics of the first power rail 324 and the second power rail 364 of the load component 310, respectively.

Some implementations of this application are directed to a dynamic electronic load that includes a set of load modules 308, a load profile modulator 332, and a set of programmable delay modules 334. Each load module 308 includes a bank of synchronously operating flip-flops 360 (FIG. 3B), and is configured to generate an output current draining from a power rail 324 and having a predefined current level. The load profile modulator 332 may be implemented as a function generator programmed to output patterned enable signals corresponding to an emulated load component 310 according to a temporal pattern 318. In other words, the set of programmable delay modules 334 control switching times of the load modules 308, thereby turning the load modules 308 between on and off. A current transient profile 326 of the emulated load component 310 may be realized by an aggregated effect of the temporal pattern 318 and the switching times of the load modules 308. An aggregated output current may be enabled to drive a power rail 324 coupled to an output of the load modules 308, and have a current transient (also called a current ramping rate) corresponding to the aggregated output current increasing to a target current level in a shortened temporal window. In some implementations, the current transient is greater than a transient threshold, e.g., when a large number of load modules 308 operate synchronously, e.g., are enabled concurrently at a common start clock edge 322S.

In some implementations, the temporal pattern 318 is repetitive at a configurable frequency to provide a periodic output current to the power rail 324, stressing a worst-case resonance impedance of a PMIC module 112 to which the electronic device 240 is coupled.

In some implementations, the dynamic electronic load chip (e.g., the electronic device 240) includes a PLL configured to generate an operating clock signal 314 based on a reference clock signal 315 for controlling operation of the set of load modules 308, the load profile modulator 332, and/or the set of programmable delay modules 334. The reference clock signal 315 is provided by an external source and has a frequency lower than that of the operating clock signal 314.

In some implementations, the dynamic electronic load chip (e.g., the electronic device 240) includes a voltage drop monitoring component 340 (e.g., a set of built-in droop measurement probes or scopes). In some implementations, the set of built-in droop measurement probes or scopes are coupled in a distributed manner, and each probe or scope is coupled to an output of a respective load module 308. The PMIC module 112 may be implemented as a distributed power delivery network, e.g., for CPU/GPU dies, and the voltage drop monitoring component 340 may be applied to characterize a spatial difference of the distributed power delivery network. In some implementations, each droop measurement probe or scope includes a ring oscillator 602 driven by the power rail 324. A voltage and frequency relationship between a voltage level of the power rail 324 and a frequency of the ring oscillator 602 is applied to generate a droop readout signal 342 indicating a voltage drop (e.g., of a voltage level of an output signal 320) at the power rail 324.

In some implementations, the voltage drop monitoring component 340 captures and stores a voltage waveform (e.g., voltage data samples) of a voltage droop event. In some situations, the voltage drop monitoring component 340 is enabled by a command 612 (FIG. 6B), according to a timer, or automatically in response to detection of a voltage change. Data samples of a voltage waveform may be stored in a FIFO memory 608 (FIG. 6B) when a capture event happen, and can be read out through a digital interface.

In some implementations, a load die chiplet that can produce load slam based on the load profile configuration. Amplitude, ramping rate, and wave shapes can be configured. Multiple load modules can be grouped for testing multiple power domains.

In some implementations, a sync signal (e.g., chiplet control signal 706 in FIG. 7) is used to synchronize load modules across a plurality of load chiplets. A chiplet synchronization module 336 (e.g., a skew detection module) is included in the dynamic load chip. The ‘sync’ signal is broadcast from a master load chip to one or more slave load chips. In some implementations, the chiplet synchronization module 336 of each electronic device 240 characterizes a relative skew between an operating clock signal 314 and the ‘sync’ signal, and generate a delay offset control signal (e.g., a first chiplet delay offset 328 in FIG. 3A). The delay offset control modulates the programmable delay modules 334 to synchronize operations of the load modules of different load chips (e.g., chiplets 702 and 704 in FIG. 7). In some implementations, load modules 308 of two or more chiplets are thereby synchronized to generate a larger current transient and a larger output current associated with the power rail 324.

In some implementations, operating clock signals 314 of two or more chiplets (e.g., chiplets 702 and 704) are calibrated to reduce a delay mismatch, e.g., below a sub-nanosecond level. In some implementations, a programmable delay is used to counteract a temporal mismatch among the start clock edges 322S of different chiplets, e.g., thereby guaranteeing different electronic load chips strike a start in a tight temporal window (e.g., within 10 nanoseconds).

Various examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.

Clause 1. An electronic device, comprising: a control signal interface configured to provide control data indicating one or more dynamic current characteristics of a load component; a clock signal interface configured to provide an operating clock signal; a load controller coupled to the control signal interface, the load controller configured to generate, based on the control data, a plurality of load control signals that are synchronized according to a temporal pattern; and a set of load modules coupled to the clock signal interface and the load controller, each load module configured to, based on a respective load control signal, generate an output signal that switches with respect to a plurality of clock edges of the operating clock signal; wherein the load controller is configured to control the set of load modules via the plurality of load control signals to generate respective output signals according to the temporal pattern, thereby allowing the set of load modules to operate jointly with respect to the plurality of clock edges to emulate the dynamic current characteristics of the load component.

Clause 2. The electronic device of clause 1, wherein the load controller further comprises: a load profile modulator coupled to the control signal interface, the load profile modulator configured to select a subset of load modules by enabling a subset of load control signals corresponding to the subset of load modules and determine a switching time for each of the subset of load modules; and a set of programmable delay modules coupled to the load profile modulator, the set of programmable delay modules are configured to generate the plurality of load control signals based on the switching time of each of the subset of load modules.

Clause 2. The electronic device of clause 1 or 2, wherein the plurality of load control signals include a first subset of load control signals, and each of the first subset of load control signals is configured to select a respective load module to operate with a respective switching time of the respective load module.

Clause 4. The electronic device of clause 3, wherein the first subset of load control signals are applied to enable a subset of load modules according to an ordered sequence based on their respective switching times, and currents of the subset of load modules are gradually aggregated to provide a stair-like current ramping profile.

Clause 5. The electronic device of any of clauses 1-4, wherein the plurality of load control signals include a second subset of load control signals, and each of the second subset of load control signals is configured to disable the respective load module.

Clause 6. The electronic device of any of clauses 1-5, wherein the clock signal interface further includes a clock generator configured to receive a reference clock signal and generate the operating clock signal based on the reference clock signal and the control data.

Clause 7. The electronic device of any of clauses 1-6, wherein each load module further includes one or more flip-flop circuits coupled to one another in parallel, and is configured to delay the operating clock signal based on the respective module control signal and feed a delayed clock signal to the one or more flip-flop circuits.

Clause 8. The electronic device of any of clauses 1-7, further comprising: a first chiplet on which the control signal interface, the clock signal interface, the load controller, and the set of load modules are integrated and formed; and one or more second chiplets distinct from the first chiplet, the one or more second chiplets configured to operate in synchronization with the first chiplet to emulate the dynamic current characteristics of the load component.

Clause 9. The electronic device of clause 8, wherein each of the first and second chiplets is configured to obtain a respective chiplet control signal to control a respective chiplet delay offset with respect to a respective remainder set of chiplets.

Clause 10. The electronic device of any of clauses 1-9, further comprising a chiplet synchronization module configured to obtain a first chiplet control signal and generate a first chiplet delay offset common to the respective output signals of the set of load modules, each respective output signal further having a respective module-level delay offset controlled by the respective load control signal.

Clause 11. The electronic device of any of clauses 1-10, further comprising: a power rail to which the set of load modules are coupled; and a voltage drop monitoring component coupled to the power rail, wherein the voltage drop monitoring component is configured to generate a droop readout signal indicating a voltage drop at the power rail.

Clause 12. The electronic device of clause 11, wherein the voltage drop monitoring component includes a ring oscillator driven by the power rail, the voltage drop monitoring component configured to monitor a frequency of a periodic signal outputted by the ring oscillator and determine the droop readout signal based on the frequency of the periodic signal.

Clause 13. The electronic device of clause 11 or 12, wherein the voltage drop monitoring component is configured to generate the droop readout signal in response to a command, according to a predefined schedule, periodically, or upon detection of a signature voltage change event.

Clause 14. The electronic device of any of clauses 11-13, further comprising: a first-in-first-out memory configured to store the droop readout signal, wherein the droop readout signal includes data samples corresponding to a signature voltage change event.

Clause 15. The electronic device of any of clauses 11-14, wherein the electronic device is electrically coupled to a power management integrated circuit (PMIC) via the power rail, and power performance of the PMIC is determined based on the droop readout signal.

Clause 16. The electronic device of any of clauses 1-15, wherein the electronic device is electrically coupled to a PMIC or a semiconductor package via a power rail of the set of load modules.

Clause 17. The electronic device of any of clauses 1-16, wherein the one or more dynamic current characteristics of the load component includes one or more of: an amplitude, a ramping rate, and a waveform shape of a current transient profile.

Clause 18. The electronic device of clause 17, wherein a first ramping rate of a first current transient profile is greater than a current ramping rate of a second current transient profile, and a set of first load modules is enabled according to the same order and different switching times to emulate both the first current transient profile and the second current transient profile, at least one of the set of first load modules having an earlier switching time for the first current transient profile than that for the second current transient profile.

Clause 19. The electronic device of any of clauses 1-18, wherein the set of load modules includes a plurality of load modules, and the plurality of load modules are controlled by the plurality of load control signals to switch simultaneously with respect to each of the plurality of clock edges.

Clause 20. The electronic device of any of clauses 1-19, wherein the set of load modules includes a first set of load modules coupled to a first power rail, and the electronic device further includes a second set of load modules coupled to a second power rail, and wherein the first set of load modules and the second set of load modules are configured to operate concurrently to emulate the dynamic current characteristics of the first power rail and the second power rail of the load component, respectively.

Clause 21. A method for testing an electronic system under a load condition, further comprising: coupling the electronic system to an electronic device; providing control data indicating one or more dynamic current characteristics of a load component; provide an operating clock signal; based on the control data, generating a plurality of load control signals that are synchronized according to a temporal pattern; and controlling a set of load modules via the plurality of load control signals to generate respective output signals according to the temporal pattern, including for each load module, generating an output signal that switches with respect to a plurality of clock edges of the operating clock signal based on a respective load control signal, wherein the set of load modules operate jointly with respect to the plurality of clock edges to emulate the dynamic current characteristics of the load component.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. An electronic device, comprising:
a control signal interface configured to provide control data indicating one or more dynamic current characteristics of a load component;
a clock signal interface configured to provide an operating clock signal;
a load controller coupled to the control signal interface, the load controller configured to generate, based on the control data, a plurality of load control signals that are synchronized according to a temporal pattern; and
a set of load modules coupled to the clock signal interface and the load controller, each load module configured to, based on a respective load control signal, generate an output signal that switches with respect to a plurality of clock edges of the operating clock signal;
wherein the load controller is configured to control the set of load modules via the plurality of load control signals to generate respective output signals according to the temporal pattern, thereby allowing the set of load modules to operate jointly with respect to the plurality of clock edges to emulate the dynamic current characteristics of the load component.

2. The electronic device of claim 1, wherein the load controller further comprises:
a load profile modulator coupled to the control signal interface, the load profile modulator configured to select a subset of load modules by enabling a subset of load control signals corresponding to the subset of load modules and determine a switching time for each of the subset of load modules; and
a set of programmable delay modules coupled to the load profile modulator, the set of programmable delay modules are configured to generate the plurality of load control signals based on the switching time of each of the subset of load modules.

3. The electronic device of claim 1, wherein the plurality of load control signals include a first subset of load control signals, and each of the first subset of load control signals is configured to select a respective load module to operate with a respective switching time of the respective load module.

4. The electronic device of claim 3, wherein the first subset of load control signals are applied to enable a subset of load modules according to an ordered sequence based on their respective switching times, and currents of the subset of load modules are gradually aggregated to provide a stair-like current ramping profile.

5. The electronic device of claim 1, wherein the plurality of load control signals include a second subset of load control signals, and each of the second subset of load control signals is configured to disable the respective load module.

6. The electronic device of claim 1, wherein the clock signal interface further includes a clock generator configured to receive a reference clock signal and generate the operating clock signal based on the reference clock signal and the control data.

7. The electronic device of claim 1, wherein each load module further includes one or more flip-flop circuits coupled to one another in parallel, and is configured to operate according to the operating clock signal during a duty cycle defined according to the respective module control signal.

8. The electronic device of claim 1, further comprising:
a first chiplet on which the control signal interface, the clock signal interface, the load controller, and the set of load modules are integrated and formed; and
one or more second chiplets distinct from the first chiplet, the one or more second chiplets configured to operate in synchronization with the first chiplet to emulate the dynamic current characteristics of the load component.

9. The electronic device of claim 8, wherein each of the first and second chiplets is configured to obtain a respective chiplet control signal to control a respective chiplet delay offset with respect to a respective remainder set of chiplets.

10. The electronic device of claim 1, further comprising a chiplet synchronization module configured to obtain a first chiplet control signal and generate a first chiplet delay offset common to the respective output signals of the set of load modules, each respective output signal further having a respective module-level delay offset controlled by the respective load control signal.

11. The electronic device of claim 1, further comprising:
a power rail to which the set of load modules are coupled; and
a voltage drop monitoring component coupled to the power rail, wherein the voltage drop monitoring component is configured to generate a droop readout signal indicating a voltage drop at the power rail.

12. The electronic device of claim 11, wherein the voltage drop monitoring component includes a ring oscillator driven by the power rail, the voltage drop monitoring component configured to monitor a frequency of a periodic signal outputted by the ring oscillator and determine the droop readout signal based on the frequency of the periodic signal.

13. The electronic device of claim 11, wherein the voltage drop monitoring component is configured to generate the droop readout signal in response to a command, according to a predefined schedule, periodically, or upon detection of a signature voltage change event.

14. The electronic device of claim 11, further comprising:
a first-in-first-out memory configured to store the droop readout signal, wherein the droop readout signal includes data samples corresponding to a signature voltage change event.

15. The electronic device of claim 11, wherein the electronic device is electrically coupled to a power management integrated circuit (PMIC) via the power rail, and power performance of the PMIC is determined based on the droop readout signal.

16. The electronic device of claim 1, wherein the electronic device is electrically coupled to a PMIC or a semiconductor package via a power rail of the set of load modules.

17. The electronic device of claim 1, wherein the one or more dynamic current characteristics of the load component includes one or more of: an amplitude, a ramping rate, and a waveform shape of a current transient profile.

18. The electronic device of claim 17, wherein a first ramping rate of a first current transient profile is greater than a current ramping rate of a second current transient profile, and a set of first load modules is enabled according to the same order and different switching times to emulate both the first current transient profile and the second current transient profile, at least one of the set of first load modules having an earlier switching time for the first current transient profile than that for the second current transient profile.

19. The electronic device of claim 1, wherein the set of load modules includes a plurality of load modules, and the plurality of load modules are controlled by the plurality of load control signals to switch simultaneously with respect to each of the plurality of clock edges.

20. The electronic device of claim 1, wherein the set of load modules includes a first set of load modules coupled to a first power rail, and the electronic device further includes a second set of load modules coupled to a second power rail, and wherein the first set of load modules and the second set of load modules are configured to operate concurrently to emulate the dynamic current characteristics of the first power rail and the second power rail of the load component, respectively.
